(19) United States
(12) Patent Application Publication
(10) Pub. No.: US 2013/0065185 A1
(43) Pub. Date: Mar. 14, 2013

(54) Scanning Lithography using point source imaging arrays

(71) Applicant: Donis G. Flagello, Scottsdale, AZ (US)

(72) Inventor: Donis G. Flagello, Scottsdale, AZ (US)

(21) Appl. No.: 13/229,582

(22) Filed: Sep. 9, 2011

(51) Int. Cl. G03F 7/20

(52) U.S. Cl. 430/322

(57) ABSTRACT

A new and useful concept for imaging a substrate is provided, that includes a source of illumination comprising a plurality of point light sources, and imaging the substrate by projecting each point light source through a near field projection schema (e.g an array of near field lens elements) to create a predetermined illumination pattern at the substrate.

### BACKGROUND

Currently in scanning projection lithography, a reticle is scanned with a uniformly illuminated slit, and the scanned slit is imaged onto the substrate (e.g. in the production of a semi conductor wafer), using a projection lens system.

### SUMMARY OF THE PRESENT INVENTION

The present invention relates to a method of imaging a substrate with a different paradigm than uniform illumination of a reticle through a slit. Specifically, the present invention provides a source of illumination comprising a plurality of point light sources, and images the substrate by projecting each point light source through a near field projection schema (e.g an array of near field lens elements) to create a predetermined illumination pattern at the substrate.

The principles of the invention can be implemented in several ways. For example, light from the plurality of point sources can be projected through a reticle that transmits light from the selected point light sources in the predetermined pattern, to enable the transmitted light to create the predetermined illumination pattern on the substrate. Moreover, the point light sources can be directed through a slit, in a manner that the point light sources illuminate and scan the reticle pattern, and the resultant image of any point on the reticle that transmits light in the predetermined pattern is a summation of the image of each spot that has illuminated the reticle point.

The present invention can also be implemented by point light sources that comprise an array of light emitting diodes (LEDs), that are selectively illuminated to produce the predetermined pattern, and wherein the illumination from the selectively illuminated LEDs are projected to the substrate by an array of near field lens elements.

The present invention can be implemented in a method that is maskless, in the sense that it does not use a reticle to produce the predetermined pattern of illumination on the substrate. With a maskless illumination concept, illumination directed from the plurality of point light sources is controlled in such a manner that only the selected point light sources that produce the predetermined illumination pattern are illuminated, and projected by the near field projection schema, to produce the predetermined illumination pattern on the substrate. In other words, the spots that are projected to the substrate turned on or off (e.g. via a controller) and projected to the near field lens array via a mirror or fiber array to provide illumination of the substrate in the predetermined pattern. Alternatively, the near field lens can have an individual light sources (e.g. LEDs) which can be turned on or off in a predetermined fashion to image spots on the substrate. This aspect of the present invention would be useful in a near field maskless lithography schema.

The method of the present invention is designed to provide good resolution, for an optical imaging system with a relatively high numerical aperature (N.A.). The near field projection schema of the invention, with lens elements in close proximity to the substrate (e.g. on the order of 50 nanometers), allows for projection from the relatively steep angles that would characterize a high NA projection system and method, and provides good resolution to such a projection system.

In this application, reference to a “point light source” means one of a series of illumination sources that are designed to be imaged, point by point, onto a substrate. Thus, a point light source can be, e.g., (i) one of an array of light emitting diodes (LED) that are imaged onto a substrate, (ii) a mirror array or an array of diffractive elements that produce a plurality of illumination sources (point sources) that are imaged point by point onto a substrate, or (iii) any other system or method in which a series of illumination sources can be resolved, point by point, onto a substrate (e.g. by the optics of the system, such as the slit, reticle, near field lens elements, optical fibers, etc.).

Also, reference to a “near field projection schema” is a schema where the last lens element (e.g. the array of near field lens elements are spaced from the substrate by a distance e.g. on the order of 50 nanometers) that is considerably less than the wavelength of the point light source(s)

Other aspects of the present invention will become further apparent from the following detailed description and the accompanying drawings.

### BRIEF DESCRIPTION OF THE DRAWINGS

FIG. 1 is a schematic illustration a method for projecting an image to a substrate, according to the present invention;

FIG. 2 is a schematic illustration of system components by which a method, according to the present invention, can be implemented; and

FIG. 3 is a schematic illustration of other system components by which a method according to the present invention can be implemented.

### DETAILED DESCRIPTION

As described above, the present invention relates to a method of imaging a substrate with a different paradigm than uniform illumination of a reticle through a slit. Specifically, the present invention provides a source of illumination comprising a plurality of point light sources. This source may be part of the individual near field lens systems or it may be projected into an individual near field lens, such as by a fiber optic. The individual near field optics lenses are part of an array of similar lenses. The total images of the point light sources from this array creates a predetermined illumination pattern at the substrate.

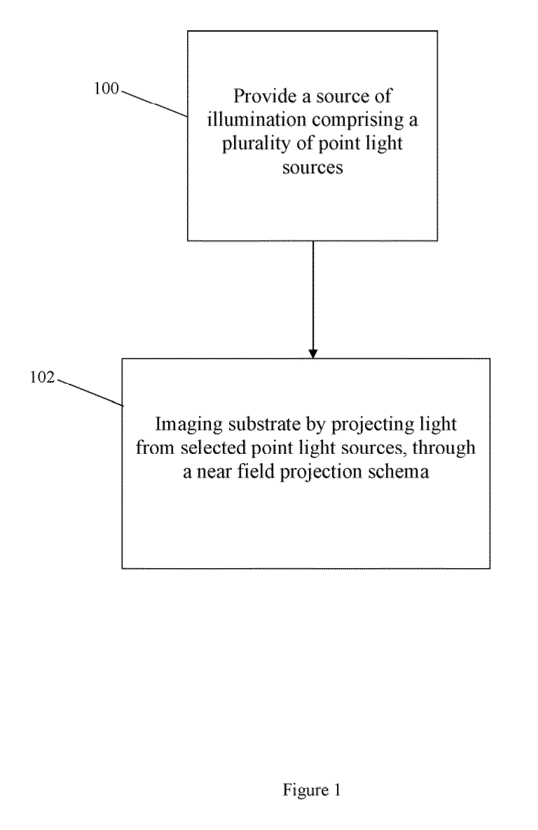

FIG. 1 is a schematic illustration of the basics of a method for projecting an image to a substrate, according to the present invention. As illustrated in FIG. 1, the method comprises providing a source of illumination comprising a plurality of point light sources (step 100), and imaging the substrate by projecting light (radiation) from selected light sources, through a near field projection schema (step 102).

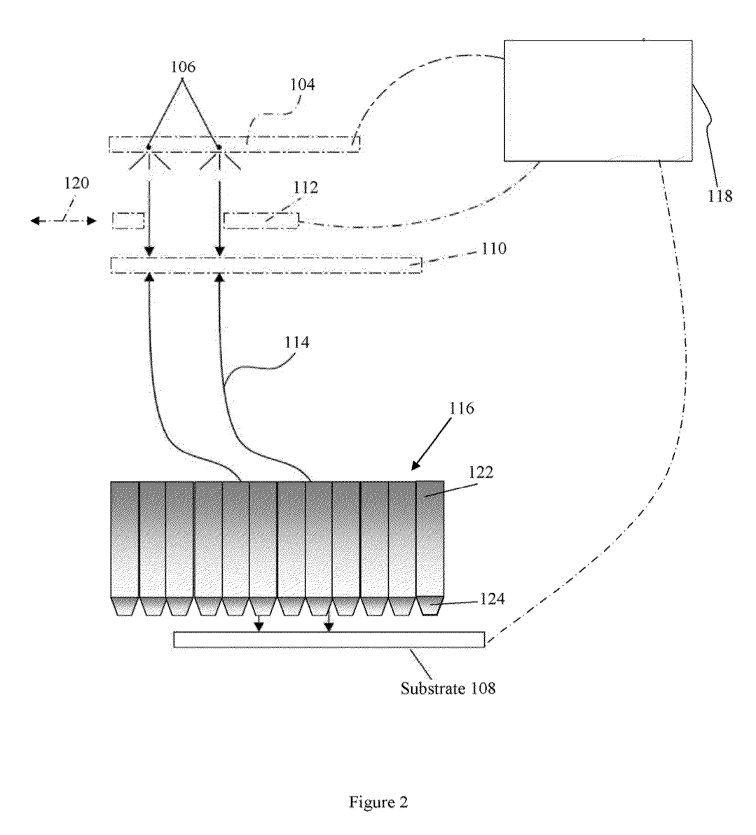

FIG. 2 is a schematic illustration of system components by which the present invention can be implemented. The system components include an illumination source 104 that comprises a plurality of point light sources 106, that produce the illumination that is directed to a substrate 108. For ease of illustration and description, two (2) point light sources 106 are shown in FIG. 2, but it will be apparent to those in the art that in fact a number of point light sources would normally be provided in a method that implements the present invention. The illumination directed to the substrate 108 is in a predetermined pattern and exposes a photoresist on the substrate 108 in that predetermined pattern. The predetermined pattern is preferably part of an electronic circuit that is produced on the substate, e.g. in the production of a semi conductor wafer.

The system components of FIG. 2 may also include any or all of the following components: a reticle or mask 110, a slit 112 through which the point light sources 106 are directed, a series of optical fibers (represented by lines 114) that direct light from the point sources to the substrate 108 through a near field lens array 116. In addition, a controller 118 can be provided, that is in circuit communication with the reticle 110, the slit 112 and the substrate (or rather the stage that supports the substrate) 108, and is configured to control the reticle, the slit and the substrate to move in a predetermined relation to each other to control the image pattern that is projected to the substrate 108. In addition, the controller 118 can be connected to the point light sources 106, to selectively turn the point light sources 106 off and on in the production of the predetermined pattern.

The method of the invention can be implemented in several ways, by means of the system components shown in FIG. 2. For example, light from the plurality of point sources 106 can be projected through the slit 112 to illuminate the reticle 110. The reticle 110 would have a predetermined pattern that transmits light from the selected point light sources 106 in the predetermined pattern, to enable the transmitted light to create the predetermined illumination pattern on the substrate. Moreover, when the point light sources are projected to the reticle 110 through the slit 112, as the slit 112 moves in a scan direction (shown schematically in FIG. 2 by the arrows 120), the point light sources 106 produce spots that illuminate and scan the reticle pattern, and the resultant image of any point on the reticle that transmits light in the predetermined pattern is a summation of the image of each spot that has illuminated the reticle point.

Light from the point light sources 106 that are directed to the substrate 108 in the predetermined pattern are projected to the substrate by a near field projection schema that includes a an array 116 of near field lens elements 122. The near field lens elements each has a diameter on the order of half a millimeter to one millimeter. The nearfield projection schema comprises projecting radiation from the point light sources to the substrate in the predetermined pattern by the array of near field lens elements 122 that are located in proximity to the substrate 108 (e.g. on the order of 50 nanometers from the substrate 108). Each of the near field lens elements 122 includes a solid immersion lens component 124 as the closest part of the near field lens element located in proximity to the substrate 108. Moreover, the array of optical fibers 114 (each of which may be a bundle of optical fibers) project radiation from the point light sources 106 to the near field lens elements 122.

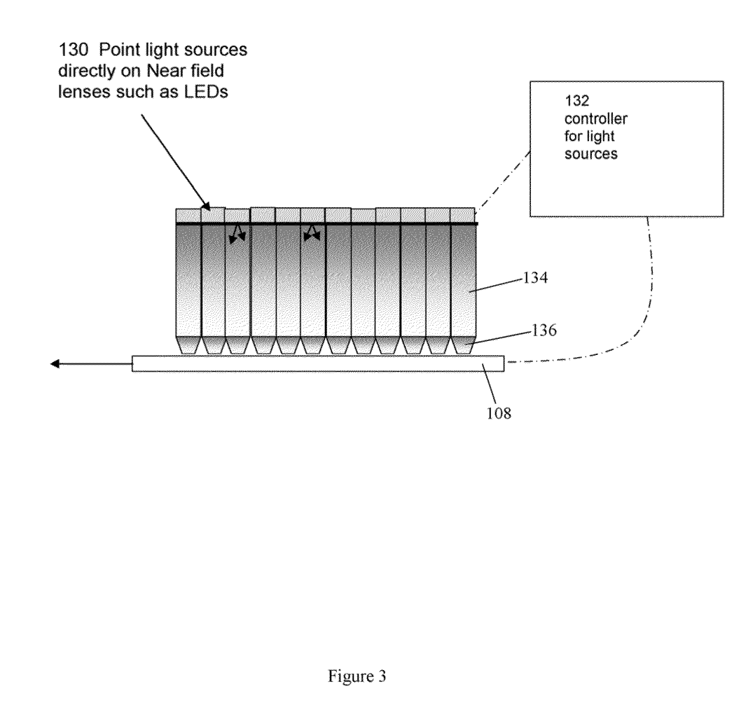

Another set of system components for projecting point light sources to the substrate, in accordance with the present invention, is shown schematically in FIG. 3. In FIG. 3, the point light sources comprises an array of light emitting diodes (LEDs) 130, that are selectively illuminated (e.g. by a controller 132 similar to the controller of FIG. 2) to produce the predetermined pattern, and wherein the illumination from the selectively illuminated LEDs are projected to the substrate 108 by an array of near field lens elements 134 that are similar to the near field lens elements of FIG. 2, and include solid immersion lens elements 136 in proximity (i.e. on the order of 50 nanometers) to the substrate. The controller 132 is in circuit communication with the LEDs 130 and is configured to control the LEDs and the substrate 108 to move in a predetermined relation to each other to control the image pattern that is projected to the substrate 108.

It should be noted that the method of the present invention is designed to provide good resolution for an optical imaging system with a relatively high numerical aperature (N.A.). The near field projection schema of the invention, with lens elements in close proximity to the substrate (e.g. on the order of 50 nanometers), allows for projection from the relatively steep angles that would characterize a high NA projection system and method, and provides good resolution to such a projection system.

The method of the present invention can also be implemented in a method that is maskless, in the sense that it does not use a reticle or a slit that moves relative to the reticle to produce the predetermined pattern of illumination on the substrate. With a maskless illumination method, illumination directed from the plurality of point light sources is controlled in such a manner that only the selected point light sources that produce the predetermined illumination pattern are illuminated (i.e. turned on), to produce the predetermined illumination pattern that is projected to the substrate by the nearfield projection schema. In other words, the spots that are projected to the substrate can be turned on or off (e.g. via a controller) and projected to the substrate via a mirror or fiber array and a near field projection schema to provide illumination of the substrate in the predetermined pattern. Alternatively, the controller could control the the pattern of the spots that illuminate the substrate by controlling a carousel, mirror array, optical array (e.g. for attenuating light), or other device that would be used in place of the reticle for controlling the spots that are imaged to the substrate by the nearfield projection schema to produce the predetermined pattern on the substrate. This aspect of the present invention would be useful in a maskless lithography schema.

Thus, the foregoing description shows various ways a substrate can be imaged using a plurality of point light sources, and projecting light from selected point light sources to create a predetermined illumination pattern at the substrate, by means of a nearfield projection schema. With the foreoing disclosure in mind, various other ways a substrate can be imaged, using a plurality of point light sources, and a nearfield projection schema, will be apparent to those in the art.

1. A method of imaging a substrate, comprising providing a source of illumination comprising a plurality of point light sources, and imaging the substrate by projecting light from selected point light sources to the substrate in a predetermined pattern, by a near field projection schema.

2. The method of claim 1, wherein imaging the substrate by a near field projection schema comprises projecting light from the plurality of point light sources through a reticle that transmits light from the selected point light sources in the predetermined pattern, to enable the transmitted light to create the predetermined illumination pattern at the substrate.

3. The method of claim 2, wherein radiation from the point light sources is projected to the reticle through a scanning slit, and wherein the scanning slit, the reticle and the substrate can move in predetermined relation to each other to produce the predetermined pattern that is projected to the substrate.

4. The method of claim 3, wherein the nearfield projection schema comprises projecting radiation from the point light sources to the substrate in the predetermined pattern by an array of near field lens elements located in proximity to the substrate.

5. The method of claim 4, wherein each of the near field lens elements includes a solid immersion lens component located in proximity to the substrate.

6. The method of claim 5, wherein an array of optical fibers project radiation from the point light sources to the near field lens elements.

7. The method of claim 1, wherein the nearfield projection schema comprises projecting radiation from the point light sources to the substrate in the predetermined pattern by an array of near field lens elements located in proximity to the substrate,

8. The method of claim 7, wherein each of the near field lens elements includes a solid immersion lens component located in proximity to the substrate.

9. The method of claim 8 wherein an array of optical fibers project radiation from the point light sources to the near field lens elements.

10. The method of claim 1, wherein the point light sources comprises an array of LEDs, that are selectively illuminated to produce the predetermined pattern, and wherein the illumination from the selectively illuminated LEDs are projected to the substrate by an array of near field lens elements.

11. The method of claim 1, wherein imaging the substrate comprises controlling illumination directed from the plurality of point light sources in a manner such that only the selected point light sources that produce the predetermined pattern are illuminated, to produce the predetermined illumination pattern that is projected to the substrate by the nearfield projection schema.
